(19) United States
(12) Patent Application Publication
(10) Pub. No.: US 2002/0012857 A1
(43) Pub. Date: Jan. 31, 2002

(54) Method of manufacturing printing plate, and printing plate

(76) Inventors: Juha Hagberg, Oulu (FI); Seppo Leppavuori, Oulu (FI)

Correspondence Address: SUGHRUE, MION, ZINN, MACPEAK & SEAS, PLLC, 2100 Pennsylvania Aveneu, N.W., Washington, DC, 20037-3213, US

(21) Appl. No.: 09/943,348

(22) Filed: Aug. 31, 2001

Related U.S. Application Data
(63) Continuation of application No. PCT/FI00/00156, filed on Feb. 29, 2000.

(30) Foreign Application Priority Data
Mar. 1, 1999 (FI) 990434

(51) Int. Cl. G03F 7/24; G03F 7/26; B41N 1/22

(52) U.S. Cl. 430/11; 430/296; 430/307

(57) ABSTRACT

The invention relates to a method of manufacturing high-accuracy printing plates, and to a printing plate. The printing plate is manufactured by depositing a layer of substance onto a base plate which is coated with a patterned resist layer. The resist layer can be further processed by means of laser. After the layer of substance has been formed, the base plate and the resist are removed, the layer of substance thus forming the printing plate, the pattern left by the resist forming the printing pattern of the plate.

This application is a Continuation of International Application PCT/F100/00156 filed on Feb. 29, 2000 which designated the U.S. and was published under PCT Article 21(2) in English.

### FIELD OF THE INVENTION

The invention relates to a solution for the manufacture of high-accuracy printing plates in particular. Printing plates are used, for example, in offset methods for printing electronic circuits, text and graphic illustrations.

### BACKGROUND OF THE INVENTION

Offset printing plates are most commonly manufactured by three methods: etching, photosensitive polymer method and laser-aided processing.

When etching is used, the areas which are not to be etched are covered with a resist layer, for example by using known photolithographic methods. The printing plate is then usually etched in an apparatus constructed for this purpose and possibly comprising circulating/nozzle systems guiding the movement of the etching agent. After the etching, the resist layer is removed from the printing plate, a patterned printing plate being thereby obtained. Etching is mostly used for manufacturing metal printing plates. A steel plate has the best durability, but the accuracy of etching on a steel plate is poor because the plate is under-etched. The etched pattern thus becomes wider and the corners of the etched grooves become rounded. Plates made of copper or brass can be etched with better accuracy than steel plates, although they are not nearly as strong in use as are steel plates. The widening of the pattern, or the amount of undercut, depends on the desired etching depth of the pattern, i.e. the etching time. Narrow lines etched with this method usually become shallow.

In a photosensitive polymer method a photosensitive polymer layer is deposited onto a solid base plate. A blank printing plate is exposed through a film or by using laser. When exposed, the polymer layer hardens, thereby becoming insoluble in the developer. The advantages of the method are its convenience and cost-efficiency, and its greater accuracy as a processing technique compared with etching. The durability of plastics is relatively poor. Narrow lines developed with this method usually become shallow.

In laser-aided processing coated metal plates are used; laser is locally applied to remove the desired pattern from the film coating the plates. The method provides the same advantages as the photosensitive polymer method. The depth of the pattern is adjusted by varying the thickness of the layer deposited. Shortcomings of the method include halftone result due to a pulsed processing technique, and relatively high investment costs.

Laser-aided processing can also be used when other materials are processed. If short, high-energy laser pulses are used, the patterns can be processed with a relatively high accuracy. However, the costs of investment and maintenance of the laser equipment concerned are high.

Current methods of manufacturing printing plates allow fairly accurate graphic printing plates to be prepared. Nevertheless, conventional processes for manufacturing printing plates are not accurate enough for the printing of conductive, resistive, dielectric or semi-conductive materials needed in electronics, for example, or to provide a desired pattern depth, finishing line accuracy and/or line width.

### SUMMARY OF THE INVENTION

An object of the invention is therefore to provide a method and printing plate allowing the above mentioned problems to be avoided. The invention relates to a method of manufacturing a printing plate which is to be used for printing patterns, a resist being used in the method to form a desired embossed pattern onto a base plate for the manufacturing of the printing plate. In the method a layer of substance is deposited onto the base plate embossed by means of the resist, thereby forming into the layer of substance a groove pattern corresponding to the desired pattern on the resist, the layer of substance being detached from the base plate patterned by means of the resist, and a printing plate being thereby formed from the layer of substance.

The invention also relates to a printing plate comprising groove patterns for printing patterns, the printing plate being arranged to be formed onto a base plate embossed by means of a resist. In addition, at the final manufacturing stage the printing plate is arranged to be detached from the base plate embossed with the resist, the printing plate comprising a layer of substance provided with a groove pattern corresponding to the desired embossed pattern on the resist.

The method and printing plate of the invention provide several advantages. Printing plates with a more precise tolerance than today can be manufactured. The invention also allows the depth of the patterns to be controlled with precision, and the simultaneous use of a plurality of pattern depths that are to be controlled, since for example the depth of the groove pattern depends on the thickness of the resist. Another aspect that can also be considered as an advantage is that the depth of the patterns does not depend on their width.

### BRIEF DESCRIPTION OF THE DRAWINGS

In the following the invention will be described in greater detail in connection with preferred embodiments and with reference to the accompanying drawings, in which

FIG. 1 illustrates a base plate with a photoresist spread onto it;

FIG. 2 illustrates irradiation of the photoresist deposited on the base plate through a photomask;

FIG. 3 illustrates the base plate coated with the irradiated photoresist that has been developed;

FIG. 4 illustrates a base plate that allows radiation to pass through, the photoresist deposited on the plate being irradiated from the reverse side of the base plate;

FIG. 5 illustrates a base plate that allows radiation to pass through, a photoresist deposited on the plate having been irradiated from the reverse side of the base plate and developed;

FIG. 6A illustrates a base plate onto which a printing plate is formed;

FIG. 6B illustrates a base plate onto which a layer of material conducting electricity and a printing plate are formed;

FIG. 7A illustrates a printing plate detached from the base plate and a support plate attached at the back of the printing plate;

FIG. 7B illustrates a printing plate detached from the base plate and a support plate attached at the back of the printing plate;

FIG. 8 illustrates a base plate that is coated twice with a resist, which is either pre-patterned or photolithographically patterned, or a combination of the two;

FIG. 9 illustrates a printing plate and a support plate attached at the back of the printing plate;

FIG. 10 illustrates a printing plate in which the edges of the patterns are not too steep;

FIG. 11 illustrates a printing plate; and

FIG. 12 illustrates a cylindrical printing plate.

### DETAILED DESCRIPTION OF THE INVENTION

A printing plate of the invention can be used for printing electronic circuits by applying an offset technique, and also for printing text and graphic illustrations, particularly by applying gravure printing, the invention not being, however, limited to these examples.

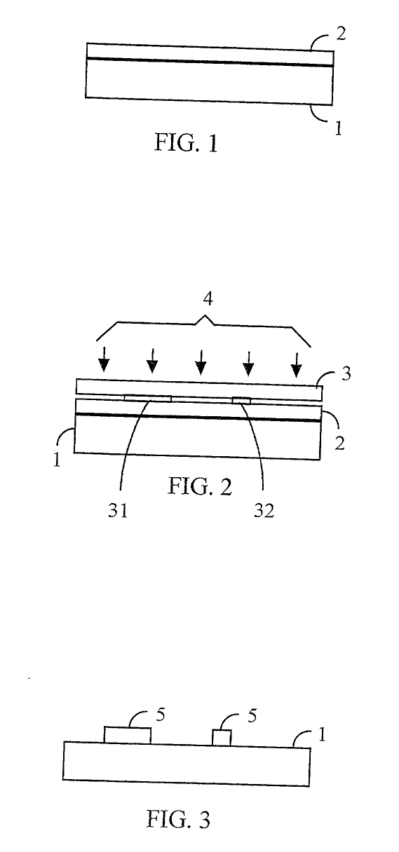

Let us first examine a method of preparing a base plate. FIG. 1 illustrates a base plate 1 onto which a photoresist 2 has been spread. The base plate 1 is usually made of glass, metal or plastic. A negative photoresist consists of a substance which hardens upon exposure, i.e. becomes insoluble into the developer. A positive photoresist, in turn, becomes soluble into the developer when it is exposed. The photoresist 2 is spread onto the base plate 1 in a manner known per se, for example by spinning, spraying or dipping. Existing photoresists include for example diazo quinone-based, epoxy, polyimide or novolak-type resists or a combination of any of them.

In FIG. 2 the photoresist 2 is exposed to radiation 4 through a mask 3. The mask 3, which is in the immediate vicinity of the base plate 1, comprises the desired pattern either as a positive or a negative, depending on whether a positive or a negative photoresist 2 is used. Areas 31 and 32 of the mask 3 do not allow the radiation 4 to pass through. The radiation 4 can be electromagnetic radiation on a band varying from X-rays to infra red radiation. In addition, particle radiation, such as electron radiation or ions, can be used. The irradiation can be carried out as a direct irradiation either through the mask 3 or without the mask 3, in which case laser can be used in addition to said irradiation methods. As distinct from FIG. 2, the mask itself can be located in optical structures of the radiation source, clearly separate from the base plate 1.

FIG. 3 illustrates a base plate coated with an irradiated photoresist 5 patterned by means of developing. The resist layer 5 is deposited onto the base plate 1 in a desired pattern form corresponding to the mask. In FIGS. 1 to 3 a positive photoresist has been used; a negative photoresist can also be used in the method.

Instead of the photoresist, a pre-patterned resist can also be used, the pattern being directly printed or transferred onto the base plate. This leads directly to the situation illustrated in FIG. 3.

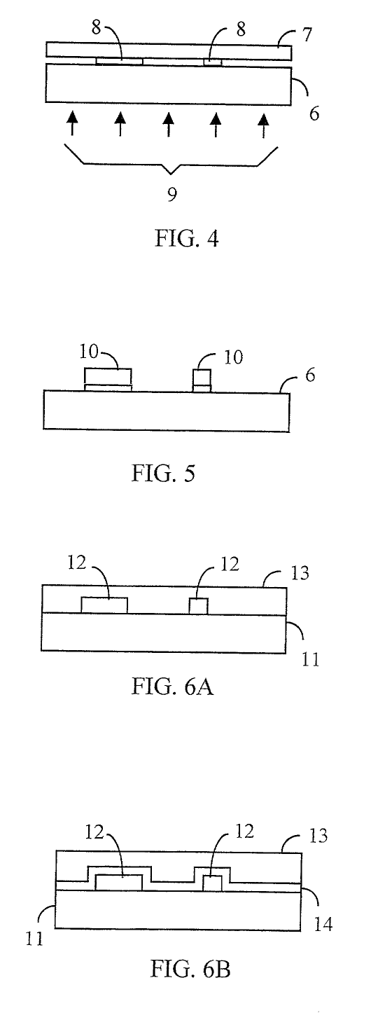

The photoresist can be alternatively irradiated by applying radiation 9 through the underside of the base plate 6 that allows radiation to pass through, as shown in FIG. 4. This requires a patterned layer 8 that does not allow radiation to pass through to be deposited onto the base plate 6 before the resist 7 is spread or before the coating. The layer 8 that does not allow radiation to pass through can be made of metal, for example.

FIG. 5 illustrates a base plate coated with an irradiated photoresist 10 that has been developed, a resist pattern 10 being thereby deposited onto the base plate 6. The photoresist is irradiated from the underside of the base plate. In FIGS. 4 to 5 a positive photoresist has been used. The method also allows a negative photoresist to be used, the mask then being a negative of the mask used in connection with the positive photoresist.

FIGS. 6A and 6B illustrate a base plate 11 coated with a patterned resist 12. In FIG. 6A the base plate 11 and the resist 12 are further coated with a layer of substance 13 forming the printing plate. The layer of substance 13 can be metal, hardened epoxy or silicone, for example. When a layer of substance 13 made of metal is used, the resist and the base plate are coated with the layer of substance 13 in a manner known per se, for example electrodeposition.

FIG. 6B illustrates a case in which the base plate is not electrically conductive. When electrodeposition is used in a case like this, it is commonly known that a thin electrically conductive layer of material 14 must first be deposited onto the base plate 11 patterned with the resist. A metal layer 13 can then be deposited onto the electrolytically conductive material layer 14.

The printing plate can also be made of silicone or hardened epoxy layered onto the resist 12 and the base plate 11 by casting or dipping, for example. The base plate can be, for example a plate made of glass, plastic or metal, or a metal folio. It may be flexible. The layer of substance forming the printing plate can be, for example silicone or epoxy that can be cast, for example onto the base plate patterned with the resist, and then hardened. The layer of substance can also be deposited by applying a solvent to provide, for example an electrodeposition or chemical deposition (electroless deposition), or a combination of the two. In electrodeposition, the surface to be coated is immersed into a solvent containing metal ions which are reduced by applying electric current to turn the surface to be coated into a cathode. In chemical deposition, the reduction of the metal ions from the solvent is achieved without external power source, such as electron exchange or a catalyst or by increasing the reducing agent, or as a combination of these. The printing plate is preferably a gravure printing plate, for example a gravure offset printing plate.

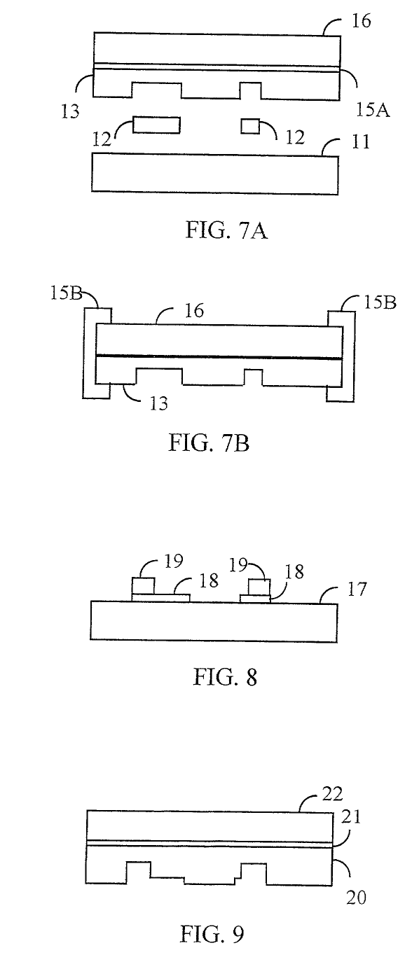

In FIGS. 7A and 7B the base plate 11 and the resist 12 have been detached from the deposited layer of substance 13, and the printing plate is attached to a support structure 16. The layer of substance 13 can be attached to the support plate 16 by means of an attaching agent 15A or by using attaching members 15B. The attaching agent 15A can be glue, such as epoxy glue. The attaching member 15B, in turn, can be a mechanical member, such as an attaching rail, or a screw. Alternatively, the attaching can be made by applying magnetic force or vacuum force. The support structure 16 may also be cast as a support for the printing plate. The support plate 16 is not, however, always needed. The layer of substance 13 thus formed provides a printing plate according to the invention.

FIG. 8 illustrates a base plate 17 which has been coated twice. The coating is first made by applying a resist 18 and then a resist 19. FIG. 9 illustrates a layer of substance deposited onto the base 17 shown in FIG. 8, and a layer of substance 20 detached from the base 17 and attached to a support plate 22 by means of glue 21. The support plate is not necessarily needed. The layer of substance 20 thus formed provides a patterned printing plate which allows the depth of the pattern groove to be adjusted according to position and pattern by varying the thickness of the resist.

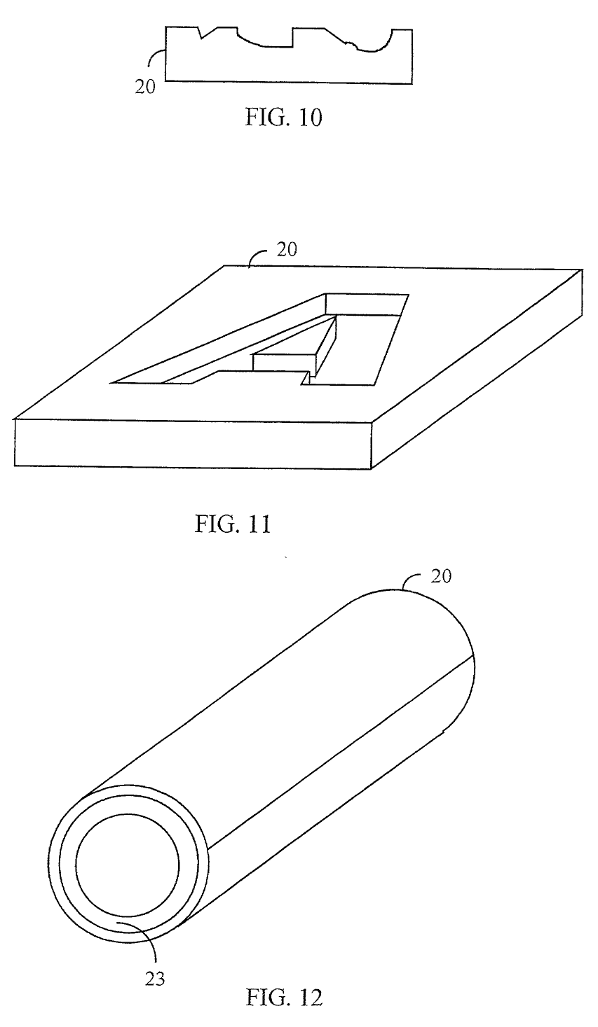

In the above Figures the masks have sharp lines. FIG. 10 shows a situation where the printing plate 20 is manufactured by using a photoresist mask having a permeability which, at least in some places, continuously and steadily changes. The printing plate 20 is thereby provided with a groove form with mildly changing edges. The structure can also be achieved by coating the base plate in advance with a resist pattern where at least in some places the pattern lines are not sharp.

FIG. 11 shows, by way of example, a printing plate with only one pattern, which is A-shaped. The depth of the pattern in the printing plate 20 is preferably 10 to 40 micrometers, but it can vary from a depth of even less than 1 micrometer to hundreds of micrometers.

FIG. 12 shows one advantageous feature of the inventive solution: the shape of the printing plate 20 can be cylindrical. The printing plate 20 can be made cylindrical without support, or the printing plate can be attached to the surface of a cylindrical support piece 23. The printing speed of the cylindrical printing plate 20 can be higher than when surface plates are used.

The printing plate of the invention allows an activation layer to be printed onto a substrate. In this case an activation layer corresponding to a pattern (a conductive pattern, for example) of the desired shape is printed onto the substrate. The desired pattern may then be deposited on top of the activation layer by applying a solvent, for example. At the start of the deposition, the activation layer acts as the catalyst. A feasible activation substance is palladium, and the substance (conductive substance) forming the pattern may be nickel or copper. An alternative is to cover the entire substrate by the activation layer for example by dipping. A resist is then printed by a printing plate of the invention to the areas which are to be free from pattern-forming substance (conductive layer).

Further, the inventive solution allows the printing plate or the resist layer spread onto the base plate to be processed in manner known per se by applying laser or electron beams (laser and electron beams allowing different materials to be cut with extreme precision). The edges of the patterns on the printing plate can thus be made steeper or flatter; the patterns can be made deeper; or entire patterns can be added onto the printing plate.

Although the invention is described above with reference to an example shown in the accompanying drawings, it is apparent that the invention is not restricted to the example, but can vary in many ways within the inventive idea disclosed in the accompanying claims.

1. A method of manufacturing a printing plate which is a gravure printing plate and which is used for printing patterns, in which method the manufacture of the printing plate comprises using a resist to pattern the desired embossed pattern onto a base plate to manufacture the printing plate; depositing a layer of substance onto the base plate embossed by means of the resist, thereby forming into the layer of substance a groove pattern corresponding to the desired pattern on the resist, the depth of the groove pattern depending on the thickness of the resist; and forming the print plate from the layer of substance by detaching the layer of substance from the base plate patterned by the resist.

2. A method of manufacturing printing plates according to claim 1, wherein the layer of substance is a metal layer deposited by means of a solvent onto the base plate patterned with the resist.

3. A method of manufacturing printing plates according to claim 1, wherein the layer of substance is a silicone layer, the printing plate being a silicone printing plate.

4. A method of manufacturing printing plates according to claim 1, wherein the layer of substance is an epoxy layer, the printing plate thus being an epoxy printing plate.

5. A method of manufacturing printing plates according to claim 1, wherein the printing plate is attached by means of an attaching agent to a support structure providing additional support.

6. A method of manufacturing printing plates according to claim 1, wherein the printing plate is attached by means of attaching members to a support structure providing additional support.

7. A method of manufacturing printing plates according to claim 5, wherein the printing plate is attached to a cylindrical support structure.

8. A method of manufacturing printing plates according to claim 6, wherein the printing plate is attached to a cylindrical support structure.

9. A method of manufacturing printing plates according to claim 1, wherein the resist layer deposited onto the base plate is a photoresist that is photolithographically patterned by applying a positive or a negative resist and by exposing the resist to radiation through a photomask.

10. A method of manufacturing printing plates according to claim 1, wherein the resist layer deposited onto the base plate is patterned by applying direct irradiation.

11. A method of manufacturing printing plates according to claim 10, wherein the direct irradiation is carried out by means of laser, a jet of electrons and/or X-rays.

12. A method of manufacturing printing plates according to claim 1, wherein the resist layer deposited onto the base plate is further processed by applying a laser-beam-aided or an electron-beam-aided technique.

13. A manufacturing method according to claim 1, wherein the resist is spread onto the base plate at least in two layers of different thickness and the resist is used to form a patterned base plate, the depth of the groove pattern on the printing plate being adjustable according to position or pattern.

14. A printing plate which is a gravure printing plate and comprises groove patterns for printing patterns, the printing plate being arranged to be formed onto a base plate embossed by means of a resist, wherein at the final manufacturing stage the printing plate is arranged to be detached from the base plate embossed with the resist, the printing plate comprising a layer of substance provided with a groove pattern corresponding to the desired embossed pattern on the resist, the depth of the groove pattern depending on the thickness of the resist.

15. A printing plate according to claim 14, wherein the printing plate is a metal layer deposited by applying a solvent onto the base plate patterned with the resist.

16. A printing plate according to claim 14, wherein the printing plate is a silicone layer that is arranged to be deposited onto the base plate patterned with the resist.

17. A printing plate according to claim 14, wherein the printing plate is arranged to be attached by means of an attaching agent to a separate support structure providing additional support.

18. A printing plate according to claim 14, wherein the printing plate is arranged to be attached by means of attaching members to a separate support structure providing additional support.

19. A printing plate according to claim 14, wherein the printing plate is cylindrical.

20. A printing plate according to any one of claims 17, wherein the printing plate is attached to a cylindrical support structure.

21. A printing plate according to any one of claims 18, wherein the printing plate is attached to a cylindrical support structure.

22. A printing plate according to any one of claims 19, wherein the printing plate is attached to a cylindrical support structure.

23. A printing plate according to claim 14, wherein the depth of the groove pattern on the printing plate varies according to pattern and/or position, and the depth of the groove pattern is adjustable by means of different stages in the manufacture of the printing plate.

24. A printing plate according to claim 14, wherein the printing plate is used for printing electronic circuits.
